(19) United States
(12) Patent Application Publication
(10) Pub. No.: US 2025/0118464 A1
(43) Pub. Date: Apr. 10, 2025

(54) CHIP RESISTOR

(71) Applicant: KOA CORPORATION, Ina-shi, Nagano (JP)

(72) Inventor: Taro KIMURA, Ina-shi (JP)

(73) Assignee: KOA CORPORATION, Ina-shi, Nagano (JP)

(21) Appl. No.: 18/726,233

(22) PCT Filed: Oct. 31, 2022
(86) PCT No.: PCT/JP2022/040638

§ 371 Date: Jul. 2, 2024

(30) Foreign Application Priority Data
Feb. 4, 2022 (JP) 2022-016590

(51) Int. Cl. H01C 17/00; H01C 1/142; H01C 17/242; H01C 17/28; H05K 3/34

(52) U.S. Cl. CPC H01C 17/006; H01C 1/142; H01C 17/242; H01C 17/283; H05K 3/3431

(57) ABSTRACT

A chip resistor includes an insulating substrate, a pair of front electrodes provided on the insulating substrate, a resistor provided to connect between the pair of front electrodes, a glass body provided on the resistor, a trimming groove formed in the resistor through the glass body, a first protective film formed to cover the trimming groove, a second protective film formed to cover the first protective film, a pair of end face electrodes formed to be connected to the front electrodes, and a pair of external plating layers formed to cover the end face electrodes, respectively, wherein the first protective film is made of a resin material containing a heat dissipating filler, and the second protective film is made of a resin material.

### TECHNICAL FIELD

The present invention relates to a surface mount chip resistor to be soldered on lands of a circuit board.

### BACKGROUND ART

A chip resistor typically includes a rectangular parallelepiped insulating substrate, a pair of front electrodes facing each other provided on the top surface of the insulating substrate with a predetermined distance therebetween, a pair of back electrodes provided on the back surface of the insulating substrate so as to face each other with a predetermined distance therebetween, a pair of end face electrodes for electrically connecting the front electrodes to the back electrodes, a pair of external plating layers for covering these electrodes, a resistor for bridging the pair of front electrodes, and an insulating protective film for covering the resistor.

In a chip resistor of this type, in typical cases, a trimming groove for adjusting a resistance value is formed in the resistor, and the protective film has a first protective film for completely covering the resistor including the trimming groove and a second protective film for completely covering the first protective film. However, in the chip resistor having the structure as described above, the thermal conductivity of the protective film is low. Accordingly, using the chip resistor in the application with a large power load causes the heat in the resistor to increase, which may lead to a destruction starting from the heat generating portion of the resistor, and further to a destruction of the entire chip resistor.

In order to provide a chip resistor for an increased power, a chip resistor having a first protective film formed of high thermal conductivity insulator particles, such as alumina, and resin, and a second protective film formed of resin, wherein the width of the first protective film is made narrower than the width of the resistor and the width of the second protective film is made wider than the width of the resistor has been conventionally proposed (see Patent Literature 1).

In the chip resistor according to Patent Literature 1, the first protective film having a high thermal conductivity covers the resistor, and is in contact with the pair of front electrodes, which allows the external plating layers to dissipate the heat generated in the resistor from the first protective film through the pair of front electrodes. Moreover, the width of the first protective film is set to be narrower than the width of the resistor, which expands a space on the insulating substrate where the second protective film is to be formed, and thus allows the second protective film to reliably protect the resistor.

### CITATION LIST

### Patent Literature

Patent Literature 1: JP-A-2019-140299

### SUMMARY OF INVENTION

### Technical Problem

In a typical chip resistor, an Ag (silver)-based metal having a low specific electrical resistance is used for the front electrodes. Although an Ag based metal is the material having a high TCR, providing the external plating layers made of Ni (nickel), Sn (tin), or the like on the front electrodes causes the reduction in the resistance value component. This enables the resistance value component of the front electrodes relative to the entire chip resistor to be reduced, and thus the TCR to be lowered. However, in the case of a chip resistor having a low resistance (for example, less than 1Ω), if it has narrow areas of the front electrodes where the external plating layers are to be formed, the effect by a TCR of the front electrode increases. Thus, the lower the resistance of the chip resistor, the more it is difficult to lower the TCR.

Here, in the chip resistor according to Patent Literature 1, the first protective film is in contact with the front electrodes while covering the connection portions where the resistor overlaps the front electrodes, and the second protective film completely covers this first protective film. In such a structure, considering that the sagging in printing may cause the outer shape of the first protective film to expand outwardly, the second protective film has to be formed sufficiently more largely than the first protective film. This makes the areas on the front electrodes where the external plating layers are to be formed narrow, and thus causes a problem of an increase in the TCR of the chip resistor having a low resistance.

The present invention has been made in view of the circumstances described above of the prior art, and an object thereof is to provide a chip resistor capable of ensuring a low TCR while being suitable for an increased power even at a low resistance.

### Solution to Problem

In order to achieve the object described above, a chip resistor according to the present invention comprises: an insulating substrate having a rectangular parallelepiped shape; a pair of electrodes formed at both ends of a main face of the insulating substrate, respectively, with a predetermined distance therebetween; a resistor formed such that both ends thereof overlap the pair of electrodes, respectively; a glass body formed on the resistor; a trimming groove for adjustment of a resistance value formed in the resistor through the glass body; a first protective film formed in an area located at an inner side from the pair of electrodes so as to cover the trimming groove; a second protective film formed so as to cover the first protective film; a pair of end face electrodes so as to extend over both end faces of the insulating substrate to be connected to the electrodes, respectively; and a pair of external plating layers formed so as to cover the end face electrodes, respectively, wherein the first protective film is made of a resin material containing a heat dissipating filler, and the second protective film is made of a resin material.

In the chip resistor having the structure as described above, the heat generated in a hot spot near the trimming groove of the resistor is dissipated through the first protective film having a high thermal conductivity. This enables the chip resistor to be suitable for increased power. Furthermore, the first protective film is prevented from flowing out onto the electrodes by the steps generated in the connection portions between the electrodes and the resistor. This enables the first protective film to be covered with the second protective film having a minimum size. As a result, sufficiently large areas where the external plating layers are to be formed in the electrodes can be secured, and thus a TCR can be prevented from increasing even in the chip resistor having a low resistance.

In the chip resistor having the structure as described above, the second protective film may be formed to extend to the areas beyond the connection portions between the electrodes and the resistor. On the other hand, forming the second protective film in an area located at an inner side from the pair of electrodes enables the areas for forming the external plating layers to be secured more largely, and also the path from the hot spot of the resistor to the external plating layers to be shortened. This allows for the efficient dissipation of the heat generated at the hot spot of the resistor toward the mounting substrate.

Furthermore, in the chip resistor having the structure as described above, forming auxiliary electrodes on the electrodes, respectively, and connecting the first protective film to the pair of external plating layers through the auxiliary electrodes enables both the ends of the resistor exposed from the first protective film to be covered with the auxiliary electrodes. In this structure, the second protective film does not necessarily have to be formed to have the shape wider than the distance between the electrodes, which improves the flexibility of the shape of the second protective film.

Furthermore, in the chip resistor having the structure as described above, forming auxiliary electrodes on the electrodes, respectively, and also making top surfaces of the pair of external plating layers covering the auxiliary electrodes and a top surface of the second protective film consecutive on substantially a same plane enables the external plating layers and the second protective film to be aligned in the height so as to form a flat top surface. This allows for stable mounting even if the area to which a nozzle absorbs is reduced when the second protective film is formed in the inner area between the electrodes.

Furthermore, in the chip resistor having the structure as described above, the auxiliary electrodes may be provided with a metal material formed by sputtering, on the other hand, forming the auxiliary electrodes with a resin material containing conductive particles enables all of the first protective film, the second protective film, and the auxiliary electrodes to be formed in the same printing process. This allows for the simplification of the producing processes.

### Advantageous Effects of Invention

According to the present invention, it is possible to provide a chip resistor capable of ensuring a low TCR while being suitable for an increased power even at a low resistance.

### BRIEF DESCRIPTION OF DRAWINGS

FIG. 1 is a top view of a chip resistor according to the first embodiment.

FIG. 2 is a cross-sectional view along the line II-II of FIG. 1.

FIG. 3 illustrates a flowchart of the producing processes of the chip resistor.

FIG. 4 is a top view of a chip resistor according to the second embodiment.

FIG. 5 is a cross-sectional view along the line V-V of FIG. 4.

FIG. 6 is a top view of a chip resistor according to the third embodiment.

FIG. 7 is a cross-sectional view along the line VII-VII of FIG. 6.

FIG. 8 is a top view of a chip resistor according to the fourth embodiment.

FIG. 9 is a cross-sectional view along the line IX-IX of FIG. 8.

FIG. 10 is a top view of a chip resistor according to the fifth embodiment.

FIG. 11 is a cross-sectional view along the line XI-XI of FIG. 10.

### DESCRIPTION OF EMBODIMENTS

Hereinafter, the embodiments of the present invention will be described with reference to the drawings.

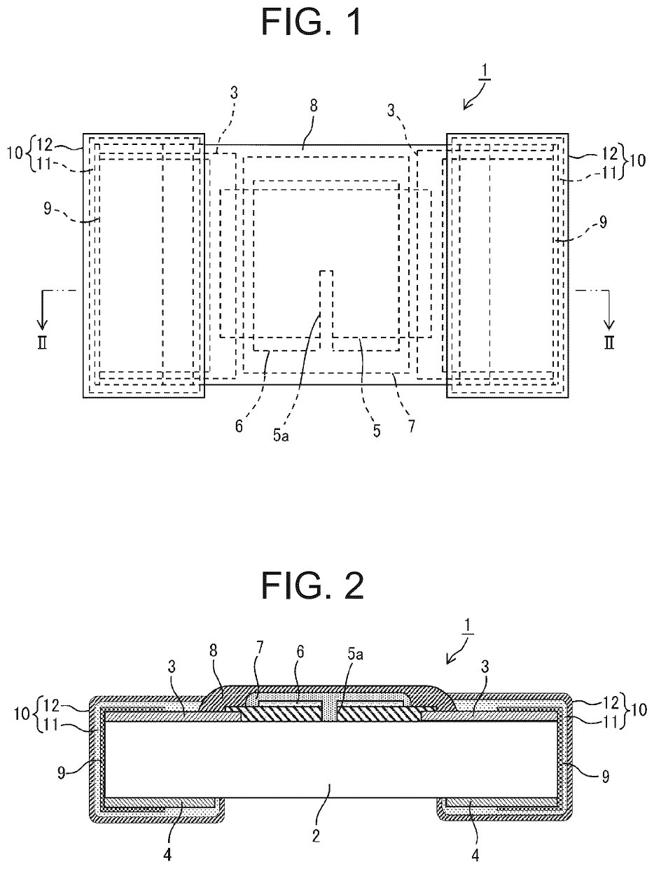

FIG. 1 is a top view of a chip resistor according to a first embodiment of the present invention, and FIG. 2 is a cross-sectional view along the line II-II of FIG. 1.

As illustrated in FIG. 1 and FIG. 2, a chip resistor 1 according to the first embodiment includes a rectangular parallelepiped insulating substrate 2, a pair of front electrodes 3 provided at both the ends in the longitudinal direction of the insulating substrate 2 on the top surface thereof, a pair of back electrodes 4 provided at both the ends in the longitudinal direction of the insulating substrate 2 on the back surface thereof, a rectangular resistor 5 provided so as to connect between the pair of front electrodes 3, a glass body 6 provided on the resistor 5, a first protective film 7 provided on the resistor 5 so as to cover the glass body 6, a second protective film 8 provided so as to completely cover the first protective film 7, a pair of end face electrodes 9 extending over both the end faces of the insulating substrate 2 so as to electrically connect between the front electrodes 3 and the back electrodes 4, and a pair of external plating layers 10 provided so as to cover the entire end face electrodes 9 and also cover the portions of the back electrodes 4 which are exposed from the end face electrodes 9.

The insulating substrate 2 is a component main body made of ceramics or the like. Each of a plurality of insulating substrates 2 is obtained by dividing a large-sized substrate along a primary division groove and a secondary division groove extending vertically and horizontally.

The front electrodes 3 are obtained by screen-printing an Ag (silver) based paste containing 1 wt % to 5 wt % of Pd (palladium) and drying and firing the printed paste. The back electrodes 4 are obtained by screen-printing an Ag paste and drying and firing the printed paste.

The resistor 5 is obtained by screen-printing a paste for resistors such as ruthenium oxide and drying and firing the printed paste. Both the ends in the longitudinal direction of the resistor 5 overlap the front electrodes 3 and connected thereto, respectively. Note that, in FIG. 2, the height of the top surface of the resistor 5, including the connection portions at both the ends thereof, is illustrated as the same over the entire resistor 5, however, practically, both the ends of the resistor overlap the front electrodes 3, which causes steps that are one level higher at the connection portions between the front electrodes 3 and resistor 5, respectively. The resistor 5 is provided with a trimming groove 5a for adjusting a resistance value, and the trimming groove 5a is formed by irradiating a laser light from above the glass body 6.

The glass body 6 is obtained by screen-printing a glass paste and drying and firing the printed paste. The glassy body 6 is formed on the resistor 5 before being provided with the trimming groove 5a, so as to cover at least the portion of the resistor 5 where the trimming groove 5a is to be formed. In the present embodiment, the glass body 6 is formed at the center portion of the resistor 5 located at the inner side from the pair of front electrodes 3, however, it may be formed so as to cover the entire of the resistor 5.

The first protective film 7 is obtained by screen-printing a resin paste, such as epoxy or phenol containing a heat-dissipating filler, and heating and curing (baking) the printed paste. The first protective film 7 is formed in an area located at the inner side from the steps generated on the connection portions between the front electrodes 3 and the resistor 5. The first protective film 7 is formed so as to cover the entire of the glass body 6 after the trimming groove 5a is provided on the resistor 5 from above the glass body 6, and thus cover the trimming groove 5a. The heat-dissipating fillers are insulator particles having high thermal conductivities such as alumina (Al₂O₃), silicon nitride (Si₃N₄), aluminum nitride (AIN), silicon carbide (SiC), boron nitride (BN), and the like.

The second protective film 8 is obtained by screen-printing a resin paste such as epoxy, phenol, or the like, and then thermal curing the printed paste. The second protective film 8 is formed to have the size allowing the resistor 5 and the first protective film 7 to be completely covered therewith, and both the ends of the second protective film 8 are in contact with the front electrodes 3 beyond the connection portions between the front electrodes 3 and the resistor 5.

The end face electrodes 9 are obtained by sputtering nickel (Ni)/chromium (Cr) or the like. Providing the end face electrodes 9 allows the front electrodes 3 and the back electrodes 4, which are separated from each other through the end faces of the insulating substrate 2, to be electrically connected to each other. The end face electrodes 9 cover not only the end faces of the insulating substrate 2, but also cover such portions of the top surfaces of the front electrodes 3 and the back surfaces of the back electrodes 4 that are located closer to the end faces of the insulating substrate 2.

Each of the external plating layers 10 has a double layer structure composed of a barrier layer 11 provided on the inner layer side and an external connection layer 12 provided on the outer layer side to cover the barrier layer 11. The barrier layer 11 is an Ni plating layer formed by electroplating, and is formed so as to cover the entire of the end face electrode 9 and such portions of the front electrode 3 and the back electrode 4 that are exposed from the end face electrode 9. The external connection layer 12 is an Sn plating layer formed by electroplating, and is formed so as to cover the entire outer surface of the barrier layer 11.

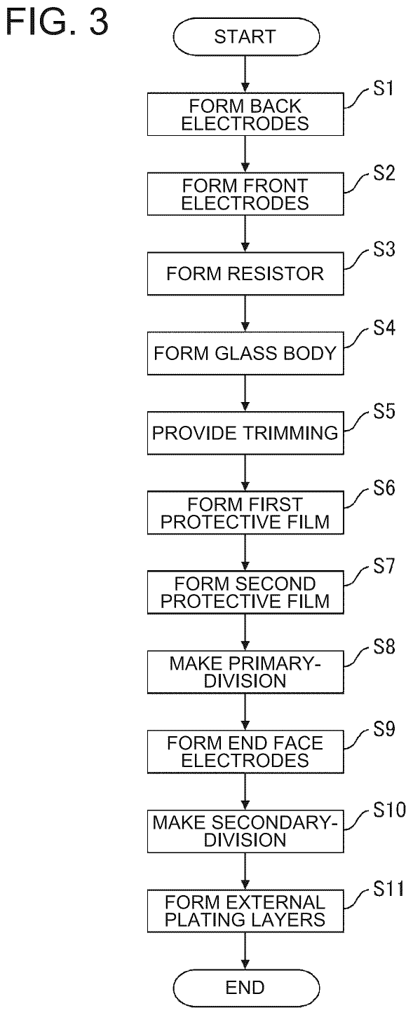

Next, a method of producing the chip resistor 1 having the structure as described above will be described with reference to a flowchart illustrated in FIG. 3.

Firstly, a large-sized substrate from which a plurality of insulating substrates 2 is obtained is prepared. The large-sized substrate is provided with primary division grooves and secondary division grooves which extend in a grid pattern, and each of the squares partitioned by these division grooves serves as one chip-forming area. As illustrated in FIG. 3, the processes to be described below are carried out collectively for this large-sized substrate.

In the first process, an Ag paste is screen-printed on the back surface of the large-sized substrate and then dried to form the pair of back electrodes 4 at both the ends in the longitudinal direction of each of the chip-forming areas, which faces each other with a predetermined distance therebetween (step S1).

Next, an Ag—Pd paste is screen-printed on the top surface of the large-sized substrate and then dried to form the pair of front electrodes 3 at both the ends in the longitudinal direction of each of the chip forming areas, which faces each other with a predetermined distance therebetween (step S2). Thereafter, the front electrodes 3 and back electrodes 4 are simultaneously fired at a high temperature of 850° C. Note that the front electrodes 3 and back electrodes 4 may be fired separately, or the order of forming them may be reversed by forming the front electrodes 3 before forming the back electrodes 4.

Next, a paste for resistors containing ruthenium oxide or the like is screen-printed on the top surface of the large-sized substrate and then dried to form the resistor 5 of which both the ends overlap the front electrodes 3, respectively, and thereafter, this resistor 5 is fired at a high temperature of 850° C. (step S3). This causes the connection portions between the front electrodes 3 and the resistor to have the steps that are one level higher.

Next, a glass paste is screen-printed on the resistor 5 located at the inner side from the pair of front electrodes 3 and dried so as to form the glass body 6 covering the center portion of the resistor 5. Thereafter, this glass body 6 is fired at a temperature of about 600° C. (step S4).

Next, while bringing a probe into contact with the pair of front electrodes 3 to measure a resistance value of the resistor 5, a laser light is irradiated from above the glass body 6, so as to form the trimming groove 5a in the resistor 5 for adjustment of the resistance value (step S5).

Next, an epoxy resin (or phenolic resin) paste including a heat-dissipating filler such as alumina is screen-printed from above the glass body 6, and then heated and cured at about a temperature of 200° C., so as to form the first protective film 7 (step S6). At this time, the resin paste of the first protective film 7 is printed on the area located at the inner side from the pair of front electrodes 3, however, the resin paste is prevented from flowing out onto the front electrodes 3 by the steps on the connection portions of the front electrodes 3 and the resistor 5 which are located at the outer side from the area where the first protective film 7 is formed.

Next, an epoxy resin (or phenolic resin) paste is screen-printed from above the first protective film 7, and then heated and cured at about a temperature of 200° C., so as to form the second protective film 8 (step S7). The second protective film 8 is formed so as to have the size allowing the resistor 5 and the first protective film 7 to be completely covered therewith, which enables the ends of the resistor 5 exposed from the first protective film 7 (connection portions with the front electrodes 3) to be covered with the second protective film 8 as well. Here, the first protective film 7 that is the lower layer of the second protective film 8 has not flown out onto the front electrodes 3, and thus the second protective film 8 does not have to be largely formed on the front electrode 3 more than necessary. In other words, such portions of the top surfaces of the front electrode 3 that are exposed without being covered with the second protective film 8 can be largely secured.

The processes described so far are collectively carried out for the large-sized substrate. On the other hand, in the next process, a primary division for the large-sized substrate is made along the primary division groove to obtain a strip-shaped substrate (step S8).

Next, sputtering of Ni/Cr is applied toward the divided faces of the strip-shaped substrate to form the pair of end face electrodes 9 that electrically connects between the front electrodes 3 and the back electrodes 4 (step S9). The end face electrodes 9 cover the entire end faces of the strip-shaped substrate and such portions of the top surfaces of the front electrodes 3 and the back surfaces of the back electrodes 4 that are located closer to the end faces of the strip-shaped substrate.

Next, after making a secondary division for the strip-shaped substrate along the secondary division groove to obtain a plurality of chip-shaped substrates (step S10), electroplating is applied on each of the chip-shaped substrates to form the pair of external plating layers 10 each having the barrier layer 11 and the external connection layer 12 (step S11). Specifically, firstly, Ni-electroplating is applied on the chip-shaped substrate to form the barrier layers 11 covering the entire end face electrodes 9 and also covers such portions of the front electrodes 3 and back electrodes 4 that are exposed from the end face electrodes 9. Thereafter, Sn-electroplating is applied on each of the chip-shaped substrates to form the external connection layers 12 covering the entire outer surfaces of the barrier layers 11. The external plating layers 10 each having a double layer structure are formed with these barrier layers 11 and external connection layers 12, and at this time, the chip resistor 1 as illustrated in FIG. 1 and FIG. 2 can be obtained.

As described above, in the chip resistor 1 according to the first embodiment, the trimming groove 5a is covered with the first protective film 7 made of a resin material containing a heat dissipating filler, and thus the heat generated in a hot spot near the trimming groove 5a of the resistor 5 is dissipated through the first protective film 7 having a high thermal conductivity. This enables the chip resistor 1 according to the first embodiment to be suitable for an increased power. Furthermore, the first protective film 7 is formed in the area located at the inner side from the pair of front electrodes 3, and thus the first protective film 7 is prevented from flowing out onto the front electrodes 3 by the steps generated on the connection portions between the front electrodes 3 and the resistor 5. This enables the first protective film 7 to be covered with the second protective film 8 having a minimum size. As a result, sufficiently large areas where the external plating layers 10 are to be formed in the front electrodes 3 can be secured, and thus a TCR can be prevented from increasing even in the chip resistor 1 having a low resistance.

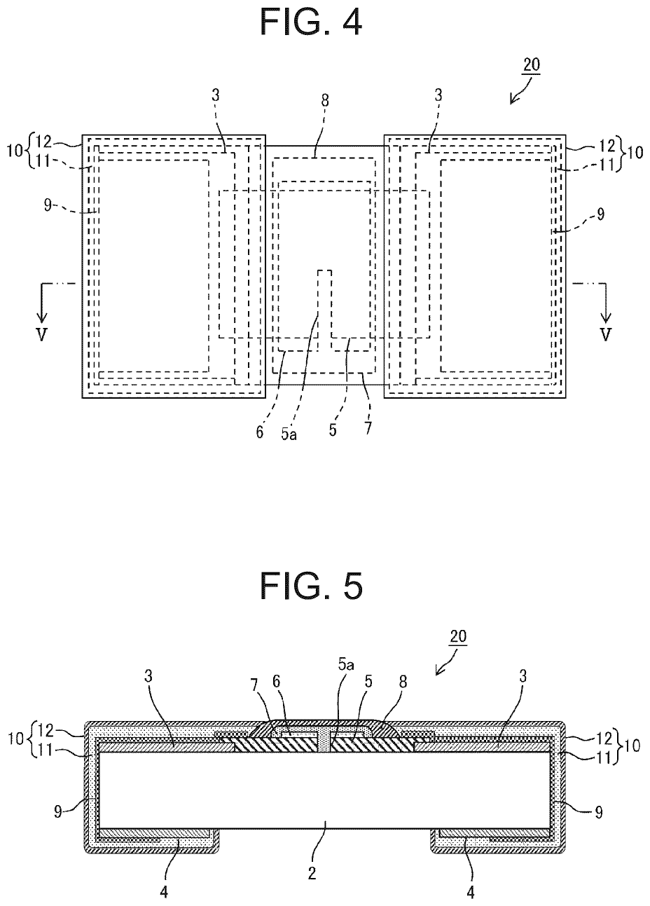

FIG. 4 is a top view of a chip resistor 20 according to a second embodiment, and FIG. 5 is a cross-sectional view along the line V-V of FIG. 4. In FIG. 4 and FIG. 5, the features corresponding to those illustrated in FIG. 1 and FIG. 2 are provided with the same reference signs.

The chip resistor 20 illustrated in FIG. 4 and FIG. 5 is different from the chip resistor 1 according to the first embodiment in that the second protective film 8 covering the first protective film 7 is formed in an area located at the inner side from the pair of front electrodes 3, and also the end face electrodes 9 cover the connection portions between the front electrodes 3 and the resistor 5 which are exposed from the second protective film 8. The other features according to the second embodiment are substantially the same as those according to the first embodiment.

In the chip resistor 20 according to the second embodiment having the structure as described above, reducing the size of the second protective film 8 causes the areas of the front electrodes 3 where the external plating layers 10 are to be formed to be secured more largely. This enables the resistance value components of the front electrodes 3 relative to the entire chip resistor to be reduced, and thus a TCR to be lowered. Furthermore, the path from the hot spot of the resistor 5 to the external plating layers 10 is shortened, which enables the heat generated at the hot spot of the resistor 5 to be efficiently dissipated toward the mounting substrate.

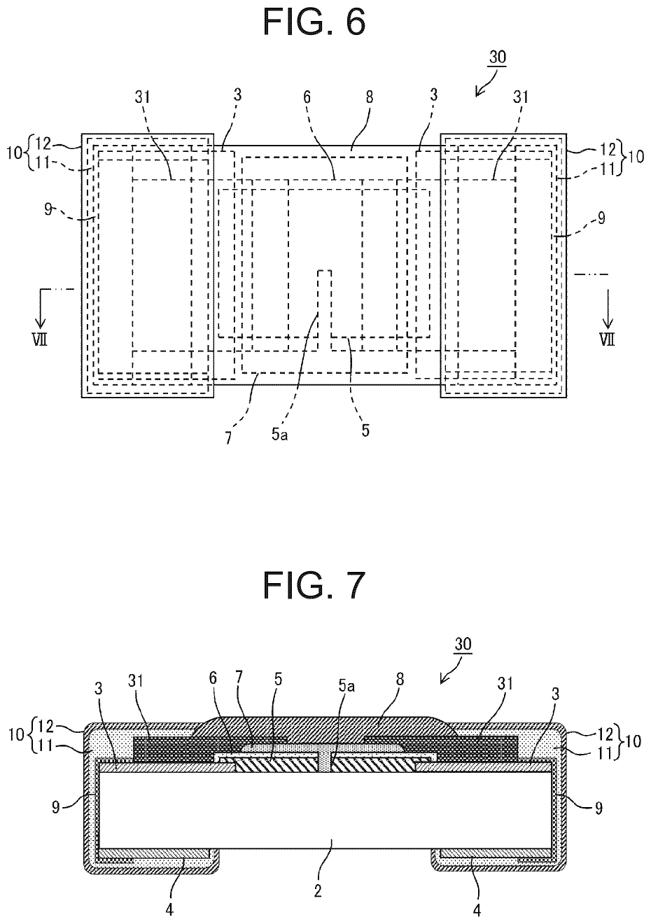

FIG. 6 is a top view of a chip resistor 30 according to a third embodiment, and FIG. 7 is a cross-sectional view along the line VII-VII of FIG. 6. In FIG. 6 and FIG. 7, the features corresponding to those illustrated in FIG. 1 and FIG. 2 are provided with the same reference signs.

The chip resistor 30 illustrated in FIG. 6 and FIG. 7 is different from the chip resistor 1 according to the first embodiment in that auxiliary electrodes 31 are formed on the pair of front electrodes 3, respectively, and the first protective film 7 and the external plating layers 10 are connected with each other via the auxiliary electrodes 31. The other features according to the third embodiment are substantially the same as those according to the first embodiment.

The auxiliary electrodes 31 are formed on such portions of the front electrodes 3 that are away from the end faces of the insulating substrate 2, and cover the connection portions between the front electrodes 3 and the resistor 5. In each of the auxiliary electrode 31, one of the ends thereof is sandwiched between the first protective film 7 and the second protective film 8. The auxiliary electrodes 31 are obtained by screen-printing a resin-paste containing conductive particles such as Ag, Cu, Ni, or the like, at the portions extending over the front electrodes 3 and the first protective film 7, and then heating and curing the printed paste at a temperature of about 200° C. That is, forming the auxiliary electrodes 31 is the process to be carried out between step S6 and step S7 in the flowchart illustrated in FIG. 3. After the auxiliary electrodes 31 are formed, the second protective film 8 is formed so as to cover such portions of the first protective film 7 that are exposed between the pair of auxiliary electrodes 31. Accordingly, all of the first protective film 7, the auxiliary electrode 31, and the second protective film 8 can be formed consecutively by screen-printing.

The auxiliary electrodes 31 may also be formed by sputtering. In this case, the auxiliary electrodes 31 are obtained by sputtering metal particles from the direction orthogonal to the top surface of the large-sized substrate with the outer portions of the pair of front electrodes 3 and the center portion of the first protective film 7 being covered with mask materials, respectively, and removing the mask material thereafter.

In the chip resistor 30 according to the third embodiment having the structure as described above, the connection portions between the front electrodes 3 and the resistor 5 which are exposed from the first protective film 7 is covered with the auxiliary electrodes 31, and thus the sputtering particles do not have to be blown toward the connection portions between the front electrodes 3 and the resistor 5 when forming the end face electrodes 9 by sputtering. This enables the end face electrodes 9 to be easily formed. Furthermore, the connection portions between the front electrodes 3 and the resistor 5 are covered with the auxiliary electrodes 31, and thus, as in the chip resistor 1 according to the first embodiment, the second protective film 8 may be shaped to be wider than the distance between the pair of front electrodes 3, or, as in the chip resistor 20 according to the second embodiment, the second protective film 8 may be shaped to be narrower than the distance between the pair of front electrodes 3. This can improve the flexibility in shaping the second protective film 8.

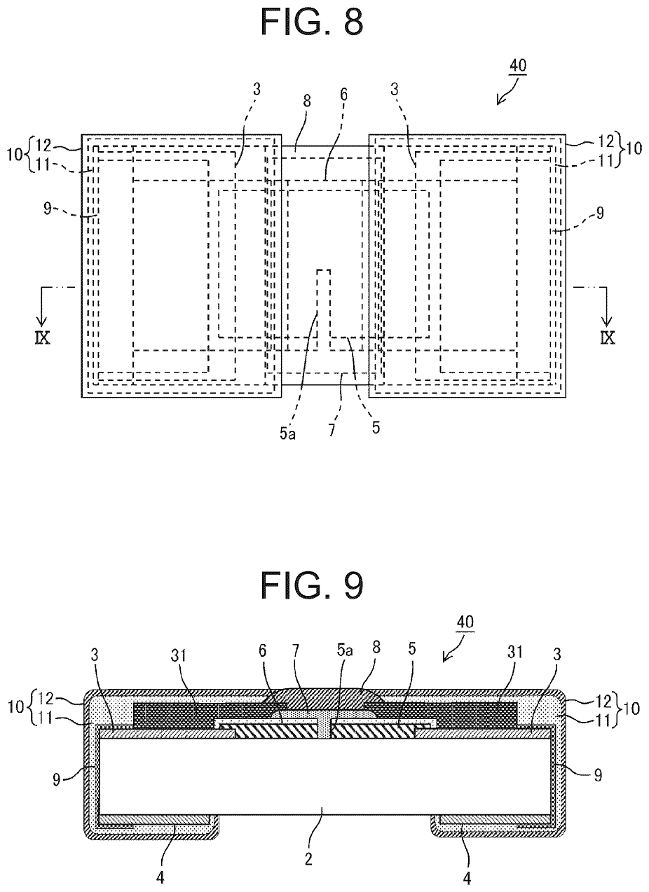

FIG. 8 is a top view of a chip resistor 40 according to a fourth embodiment, and FIG. 9 is a cross-sectional view along the line IX-IX of FIG. 8. In FIG. 8 and FIG. 9, the features corresponding to those illustrated in FIG. 6 and FIG. 7 are provided with the same reference signs.

The chip resistor 40 illustrated in FIG. 8 and FIG. 9 is different from the chip resistor 30 according to the third embodiment in that the second protective film 8 covering the first protective film 7 is formed in the area located at the inner side from the pair of front electrodes 3, and the top surfaces of the outer plating layers 10 and the top surface of the second protective film 8 are consecutive on substantially the same plane. The other features according to the fourth embodiment are substantially the same as those according to the third embodiment.

In the chip resistor 40 according to the fourth embodiment having the structure as described above, forming the second protective film 8 in the inner area between the pair of front electrodes 3, which enables the areas of the front electrodes 3 in which the external plating layers 10 are to be formed to be secured more largely, and thus a TCR to be lowered. On the other hand, in such a structure, when the chip resistor 40 is made adsorbed using a nozzle and mounted on the mounting substrate, the area of the second protective film 8 to which the nozzle absorbs is reduced. However, the external plating layers 10 and the second protective film 8 are aligned in the height so as to form a flat top surface, which enables the chip resistor 40 to be mounted stably.

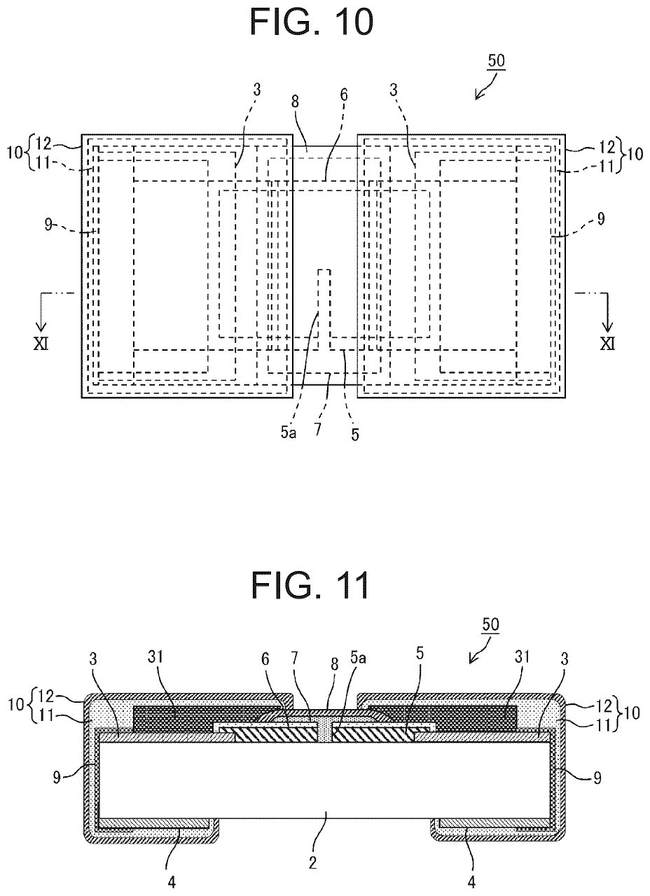

FIG. 10 is a top view of a chip resistor 50 according to a fifth embodiment, and FIG. 11 is a cross-sectional view along the line XI-XI of FIG. 10. In FIG. 10 and FIG. 11, the features corresponding to those illustrated in FIG. 8 and FIG. 9 are provided with the same reference signs.

The chip resistor 50 illustrated in FIG. 10 and FIG. 11 is different from the chip resistor 40 according to the fourth embodiment in that, in each of the auxiliary electrodes 31, one of the ends thereof is not sandwiched between the first protective film 7 and the second protective film 8 but is in contact with the upper end of the second protective film 8. The other features according to the fifth embodiment are substantially the same as those according to the fourth embodiment.

In the chip resistor 50, the second protective film 8 is formed in the area located at the inner side from the pair of front electrodes 3, and the first protective film 7 is completely covered with the second protective film 8. The auxiliary electrodes 31 are obtained by screen-printing a resin-paste containing conductive particles such as Ag, Cu, Ni, or the like, at the portions extending over the front electrodes 3 and the resistor 5, and then heating and curing the printed paste at about a temperature of 200° C. That is, forming the auxiliary electrodes 31 is the process to be carried out between step S7 and step S8 in the flowchart illustrated in FIG. 3. After the second protective film 8 covering the first protective film 7 is formed, the pair of auxiliary electrodes 31 is formed so as to cover the upper end portions of the second protective film 8 beyond both the ends thereof.

In the chip resistor 50 according to the fifth embodiment having the structure as described above, forming the pair of auxiliary electrodes 31 so as to cover up to the upper end portions of the second protective film 8 and forming the external plating layers 10 so as to cover the auxiliary electrodes 31 causes the increase in the area of the portions of the auxiliary electrodes 31 which are exposed on the top surface of the chip resistor 50. As a result, not only a TCR can be lowered, but also a large plane for the auxiliary electrodes 31 can be secured on the top surface of the chip resistor 50, which enables the chip resistor 40 to be mounted stably.

The present invention is not limited to the embodiments described above, and various modifications can be made without departing from the technical concept thereof. For example, in the embodiments described above, a chip resistor provided with the back electrodes to be electrically connected to the front electrodes on the back surface of the insulating substrate has been described, however, the present invention is also applicable to a chip resistor of the type not provided with such back electrodes.

### REFERENCE SIGNS LIST

1, 20, 30, 40, 50 chip resistor
2 insulating substrate
3 front electrode (electrode)
4 back electrode
5 resistor
5a trimming groove
6 glass body
8 second protective film
9 end face electrode
10 external plating layer
11 barrier layer
12 external connection layer
31 auxiliary electrode

1. A chip resistor comprising:
an insulating substrate having a rectangular parallelepiped shape;
a pair of electrodes formed at both ends of a main face of the insulating substrate, respectively, with a predetermined distance therebetween;
a resistor formed such that both ends thereof overlap the pair of electrodes, respectively;
a glass body formed on the resistor;
a trimming groove for adjustment of a resistance value formed in the resistor through the glass body;
a first protective film formed in an area located at an inner side from the pair of electrodes so as to cover the trimming groove;
a second protective film formed so as to cover the first protective film;
a pair of end face electrodes formed so as to extend over both end faces of the insulating substrate to be connected to the electrodes, respectively; and
a pair of external plating layers formed so as to cover the end face electrodes, respectively, wherein
the first protective film is made of a resin material containing a heat dissipating filler, and
the second protective film is made of a resin material.

2. The chip resistor according to claim 1, wherein
the second protective film is formed in an area located at an inner side from the pair of electrodes.

3. The chip resistor according to claim 1, wherein
auxiliary electrodes are formed on the electrodes, respectively, and
the first protective film is connected to the pair of external plating layers through the auxiliary electrodes.

4. The chip resistor according to claim 2, wherein
auxiliary electrodes are formed on the electrodes, respectively, and
top surfaces of the pair of external plating layers covering the auxiliary electrodes and a top surface of the second protective film are consecutive on substantially a same plane.

5. The chip resistor according to claim 2, wherein
the auxiliary electrodes are made of a resin material containing conductive particles.

6. The chip resistor according to claim 2, wherein
auxiliary electrodes are formed on the electrodes, respectively, and
the first protective film is connected to the pair of external plating layers through the auxiliary electrodes.

7. The chip resistor according to claim 3, wherein
the auxiliary electrodes are made of a resin material containing conductive particles.

8. The chip resistor according to claim 4, wherein
the auxiliary electrodes are made of a resin material containing conductive particles.

9. The chip resistor according to claim 5, wherein
the auxiliary electrodes are made of a resin material containing conductive particles.
